(19) United States
(12) Patent Application Publication
(10) Pub. No.: US 2013/0289902 A1
(43) Pub. Date: Oct. 31, 2013

(54) ANOMALY DETECTION UTILIZING ENERGY FLOW NETWORKS

(71) Applicant: Alex Nugent, Santa Fe, NM (US)

(72) Inventor: Alex Nugent, Santa Fe, NM (US)

(73) Assignee: Knowm Tech, LLC

(21) Appl. No.: 13/608,058

(22) Filed: Sep. 10, 2012

Related U.S. Application Data
(60) Provisional application No. 61/640,271, filed on Apr. 30, 2012.

(51) Int. Cl. G01R 31/40; H02J 4/00; G06F 19/00

(52) U.S. Cl. 702/58; 307/43

(57) ABSTRACT

A fabric of cores can be configured to spontaneously organize internal structure that mirrors the spatial-temporal causal structure of the data stream that is injected into the fabric. The mechanism is that of a self-organizing energy dissipating structure such that the energetic source is the injected signals and the energetic sink is the collisions of signals in cores. An adaptive routing architecture is further possible such that energy is preferentially allocated in the direction of maximal energy sink. By measuring the energy dissipation rate, anomalies may be detected by comparing to a set threshold.

### CROSS-REFERENCE TO PROVISIONAL APPLICATION

This application clams priority under 35 U.S.C. 119(e) to U.S. Provisional Patent Application Ser. No. 61/640,271, entitled “Anomaly Detection Utilizing Energy Flow Networks,” which was filed on Apr. 30, 2012 the disclosure of which is incorporated herein by reference in its entirety.

### TECHNICAL FIELD

Embodiments are generally related to the detection of anomalies. Embodiments additionally relate to spatial-temporal data streams and the extraction of spatial-temporal regularities, features, and patterns. Embodiments additionally relate to techniques, devices, and systems for analyzing and/or processing spatial-temporal data streams. Embodiments further relate to energy flow networks and applications thereof.

### BACKGROUND

There exists an urgent need to protect vital public and private infrastructure from unauthorized cyber threats. As one example, a user of a particular computer system may have their username and password compromised. It would be extremely helpful to the lawful owner of the system to be alerted to use of the system should the patterns or behaviors of the system deviate from what is normal. Such a capability could be afforded by a continuously adaptive system operating in the background learning the patterns and regularities associated with the particular user. Upon detection of changes in the normal patterns of behavior, such a system could sound an alert to interested parties. Other applications exist, for example, in the monitoring of industrial equipment. A device that monitors the normal modes of operation, for example, the sequences of a robotic arm or a centrifuge, would learn to recognize the normal patterns of usage. If the system deviates from normal patterns, an alert is sent to system administrators or the device is powered down. Other uses could entail recognitions of changes in financial market dynamics. Such a device, system and methods thereof are described in greater detail herein.

### BRIEF SUMMARY

The following summary of the invention is provided to facilitate an understanding of some of the innovative features unique to the present invention, and is not intended to be a full description. A full appreciation of the various aspects of the invention can be gained by taking the entire specification, claims, drawings, and abstract as a whole.

It is, therefore, one aspect of the disclosed embodiments to provide for the detection of anomalies.

It is another aspect of the disclosed embodiments to provide for the processing of spatial-temporal data streams and the detection of regularities within such data streams.

It is still another aspect of the disclosed embodiments to provide for self-organizing energy flow networks and devices, methods and systems, and the utilization of such networks for pattern recognition and anomaly detection.

The aforementioned aspects and other objectives and advantages can now be achieved as described herein. An anomaly-detecting fabric apparatus, system, and method are disclosed herein. In general, a plurality of interacting cores can be configured in a nodal network having a link structure, wherein the cores receive and process a spatial-temporal data stream. Each core can be configured to solve for anomaly detection by creating energy during sensory input to the at least one input and a dissipation of energy during collisions of nodal activations with respect to the nodal network. One or more inputs can be provided to each core among the plurality of interacting cores. Such inputs generally provide the aforementioned spatial-temporal data stream, and each core can receive one or more of the inputs and functions as a regularity detector to recognize statistical regularities with respect to the input(s) and permit the interacting cores to detect anomalies with respect the spatial-temporal data stream.

A number of embodiments preferred and alternative are disclosed herein. For example, in one embodiment a spatial-temporal regularity extraction fabric apparatus can be disclosed which includes a plurality of interacting cores, wherein the plurality of interacting cores receives activations containing energy or particles, wherein each core among the plurality of interacting cores is configured to map input activation patterns arising from external nodal activations to internal nodes within the plurality of interacting cores, and wherein the energy or the particles are transferred between the internal nodes within the plurality of interacting cores.

In another embodiment, the aforementioned energy can be liberated when the activations collide within at least one core among the plurality of interacting cores. In other embodiments, the spatial-temporal regularity extraction fabric apparatus can be configured for anomaly detection.

In another embodiment, a change in a power dissipation rate can be compared to a threshold value and employed to trigger an alert regarding the anomaly detection.

In yet other embodiments, the aforementioned energy can be liberated when the activations collide within at least one core among the plurality of interacting cores. In other embodiments, the spatial-temporal regularity extraction fabric apparatus can be configured for anomaly detection.

In other embodiments, a change in a power dissipation rate can be compared to a threshold value and employed to trigger an alert regarding the anomaly detection,

In another embodiment, a spatial-temporal regularity extraction fabric apparatus can include a plurality of interacting cores, wherein the plurality of interacting cores receives activations containing energy or particles, wherein each core among the plurality of interacting cores is configured to map input activation patterns arising from external nodal activations to internal nodes within the plurality of interacting cores, and wherein the energy or the particles are transferred between the internal nodes within the plurality of interacting cores, wherein the energy is liberated when the activations collide within at least one core among the plurality of interacting cores and wherein the spatial-temporal regularity extraction fabric apparatus is configured for anomaly detection.

In another embodiment, an apparatus for adaptive energy allocation can be included, which includes a plurality of memristors that function as adaptive energy flow conduits.

In another embodiment, an anomaly-detecting fabric system can include a plurality of interacting cores in a nodal network having a link structure, wherein the plurality of interacting cores receives and processes a spatial-temporal data stream, wherein each core among the plurality of interacting cores is configured to solve for anomaly detection by creating energy during sensory input to the at least one input and a dissipation of energy during collisions of nodal activations with respect to the nodal network; and at least one input to each core among the plurality of interacting cores, the at least one input providing the spatial-temporal data stream, wherein the each core among the plurality of interacting cores receives the at least one input and functions as a regularity detector to recognize statistical regularities with respect to the at least one input and permit the plurality of interacting cores to detect anomalies with respect to the spatial-temporal data stream.

In another embodiment, the aforementioned input lines can receive inputs that share a high degree of mutual information. In other embodiments, each nodal activation can comprise a particle. In yet other embodiments, a prediction can be defined as at least one collision of two or more particles at at least one core among the plurality of interacting cores, which form a regularity detectable by the regularity detector. In other embodiments, when the at least one collision occurs, energy can be liberated from the nodal network causing increased energy flow in a direction of the at least one collision and a reinforcement of the link structure.

In yet another embodiment, after a period, a stable flow structure occurs, which acts to annihilate energy introduced to the sensory inputs via particle collisions so that the stable flow structure mirrors a structure of the spatial-temporal data stream. In still other embodiments, the aforementioned input lines can receive inputs that share a high degree of mutual information and wherein each nodal activation comprises a particle.

In another embodiment, a method for configuring a spatial-temporal regularity extraction fabric apparatus can be implemented. Such a method can include, for example, the steps or logical operations of providing a plurality of interacting cores, wherein the plurality of interacting cores receives activations containing energy or particles; and configuring each core among the plurality of interacting cores to map input activation patterns arising from external nodal activations to internal nodes within the plurality of interacting cores such that the energy or the particles are transferred between the internal nodes within the plurality of interacting cores.

In another embodiment, the aforementioned can be liberated when the activations collide within at least one core among the plurality of interacting cores. In other embodiments, a step or logical operation can be implemented for configuring the spatial-temporal regularity extraction fabric apparatus for anomaly detection.

In other embodiments, a change in the power dissipation rate can be compared to a threshold value and employed to trigger an alert regarding the anomaly detection. In still other embodiments, the aforementioned energy can be liberated when the activations collide within at least one core among the plurality of interacting cores.

### BRIEF DESCRIPTION OF THE DRAWINGS

The accompanying figures, in which like reference numerals refer to identical or functionally-similar elements throughout the separate views and which are incorporated in and form part of the specification, further illustrate the present invention and, together with the detailed description of the invention, serve to explain the principles of the present invention.

FIG. 1 illustrates a schematic diagram of cores arranged in a fabric architecture, which may (or may not) be locally-connected, in accordance with the disclosed embodiments,

FIG. 2 illustrates a schematic diagram of three possible interactions in accordance with the disclosed embodiments;

FIG. 3 illustrates a schematic diagram demonstrating how once node capacity has been attained, the nodes will fill up and prevent flow, in accordance with the disclosed embodiments;

FIG. 4 illustrates a schematic diagram at various times demonstrating how two or more memristors may act as adaptive energy flow conduits which will increase conductance as energy flows through them, in accordance with the disclosed embodiments; and

FIG. 5 illustrates a schematic diagram demonstrating how particle collisions create regions of energy sink, which lead to flow-stabilization over links in a link structure, in accordance with the disclosed embodiments.

### DETAILED DESCRIPTION

The particular values and configurations discussed in these non-limiting examples can be varied and are cited merely to illustrate an embodiment of the present invention and are not intended to limit the scope of the invention.

The embodiments will now be described more fully hereinafter with reference to the accompanying drawings, in which illustrative embodiments of the invention are shown. The embodiments disclosed herein can be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout. As used herein, the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As indicated previously, there exists an urgent need to protect vital public and private infrastructure from unauthorized cyber threats. As one example, a user of a particular computer system may have their username and password compromised. It would be extremely helpful to the lawful owner of the system to be alerted to use of the system should the patterns or behaviors of the system deviate from what is normal. Such a capability could be afforded by a continuously adaptive system operating in the background learning the patterns and regularities associated with the particular user. Upon detection of changes in the normal patterns of behavior, such a system could sound an alert to interested parties. Other applications exist, for example in the monitoring of industrial equipment. A device, which monitors the normal modes of operation, for example, the sequences of a robotic arm or a centrifuge, would learn to recognize the normal patterns of usage. If the system deviates from normal patterns, an alert is sent to system administrators or the device is powered down. Other uses could entail recognitions of changes in financial market dynamics. Such a device and methods and systems are discussed in greater detail herein,

What is required to solve the problem of anomaly detection in all its most general forms is a general-purpose fabric, which continuously learns the algorithmic structure of spatial-temporal sensory inputs. The structure of the sensory data stream becomes reflected in the algorithmic structure grown within the fabric of the device. So long as the sensory spatial-temporal structure remains, the internal algorithmic structure of the fabric remains stable. If the external sensory data structure changes, the structure within the fabric adapts, either collapsing or growing, or both. This adaptation is detected indirectly as a decrease or increase in the power dissipation of the system, either globally or in sub-regions on the chip.

The function and structure of the anomaly-detecting fabric is described generally as follows. The fabric is composed of many interacting cores. Each core acts as a spatial regularity detector, which has been described in detail in other disclosures. The core function of a core is to recognize statistical regularities on its input lines, defined as inputs that share a degree of mutual information. That is, two inputs that are always active and non-active at the same time can be treated as the same information source.

Regularity detection concerns the recognition of distinct states from potentially many temporal varying inputs, which may contain noise and statistical drift over time. Regularity detection is not the same as but similar to clustering. In clustering, for example through the k-means algorithm, the user specifies a number of cluster centers and the input patterns are mapped to these cluster centers, which are in turn adjusted to reflect statistical distributions. This method is generally useful but fails with some distributions, most notably density-based distributions. It suffers a few serious and intrinsic problems. First, the user must specify ahead of time how many cluster centers to use. Second, as the number of features or regularities in the data distribution increases, more cluster centers must be added. Third, a pattern match must be made against every cluster center so that, for example, a data distribution with 1,000 regularities would require at least 1,000 centers and 1,000 comparison operations per cycle, Regularity extraction, for example, through the use of AHaH nodes as detailed in other disclosures, alleviates all of these problems. Most generally, however, regularity detection concerns the unsupervised problem of taking an input X and producing one or more labels L representing the statistical regularities in the input data distribution.

Each core performs regularity detection on its inputs and associates with each regularity one of a set number of internal nodes, Furthermore, each core handles the transfer of energy between nodes as well as the strengthening and weakening of link weights, which associates each node within cores to other cores in the fabric.

To review, the function of each core is to detect the current regularity formed from the activation of a number of inputs to the core at a specified time step or period, associate this regularity with an internal node, perform energy-transfer operations between sending and receiving nodes, and to update the weights of links which represent the connections between node and cores.

To configure cores to solve the anomaly-detection problem we must provide for the creation of energy during sensory input and the dissipation of energy during collisions of nodal activations. We will refer to a nodal activation as a particle. We will define a prediction as the collision of two or more particles at a core, thus forming a regularity. When a collision occurs, energy is liberated from the nodal network causing for increased energy flow in the direction of collisions and the reinforcement of link structure. After a period, a stable flow structure is created which acts to annihilate the energy introduced to the fabric through its sensory inputs via particle collisions. This stable flow structure mirrors the structure of the underlying spatial-temporal data stream.

To fully understand this process, let us start with a metaphorical description. We will then proceed to decompose the operations of a core into its basic functions and disclose how such a fabric can be realized. We will then develop a higher-level abstraction that will allow us to understand the basic principles at work. It will then become clear how anomaly-detection fabric grows internal structure to mirror the algorithmic spatial-temporal structure of the datastream it is processing.

Picture a newly formed water spring on the top of a mountain plateau or high plain, spewing water out onto the mostly flat surface. At first the water spreads out uniformly, moving toward the cliff faces on all sides. At some point, the water falls off one side of the mountain, precipitating erosion of the sandy edge surface, Over time, the flow of water erodes a channel from the spring to the cliff face, forcing the water through a specific path.

This metaphor is similar to the process we are utilizing in our anomaly detection fabric. Note that for the water to flow and for the erosion to take place, the water must be carried off the plateau. In other words, there has to be a sink for the spring's source. Without a sink, the water will build up but no channels will form. Anomaly-detection fabric forces the flow of packets of energy, called particles, through nodes such that discrete logic circuits are created and stabilized. By removing energy when a collision of particles occurs, we create energy sinks for “prediction events”. Regularity extractions followed by evolution of link structure is computationally equivalent to forming logical networks. Thus, the fabric spontaneously organizes logic pathways that take inputs to predict future inputs, a state that will dissipate the most energy by creating structures that ensure maximal particle collisions.

Only circuits that reliably lead to energy sinks are stable over time, since the strength of a connection is a function of the energy that flows over the connections. The only stable structures are algorithmic pathways that predict spatial-temporal structure. The more predictable the data stream, the more particle collisions are possible and the more energy can be dissipated. By measuring the total energy dissipation of the fabric, globally or locally, we can measure the degree of predictive structure within the fabric. After allowing for a period of adaptation while internal structure is grown, changes in the power dissipation can be used as a measure of an underlying change in the structure of the data stream. That is, changes in fabric power dissipations after periods of stasis can be used as an indication of an anomaly,

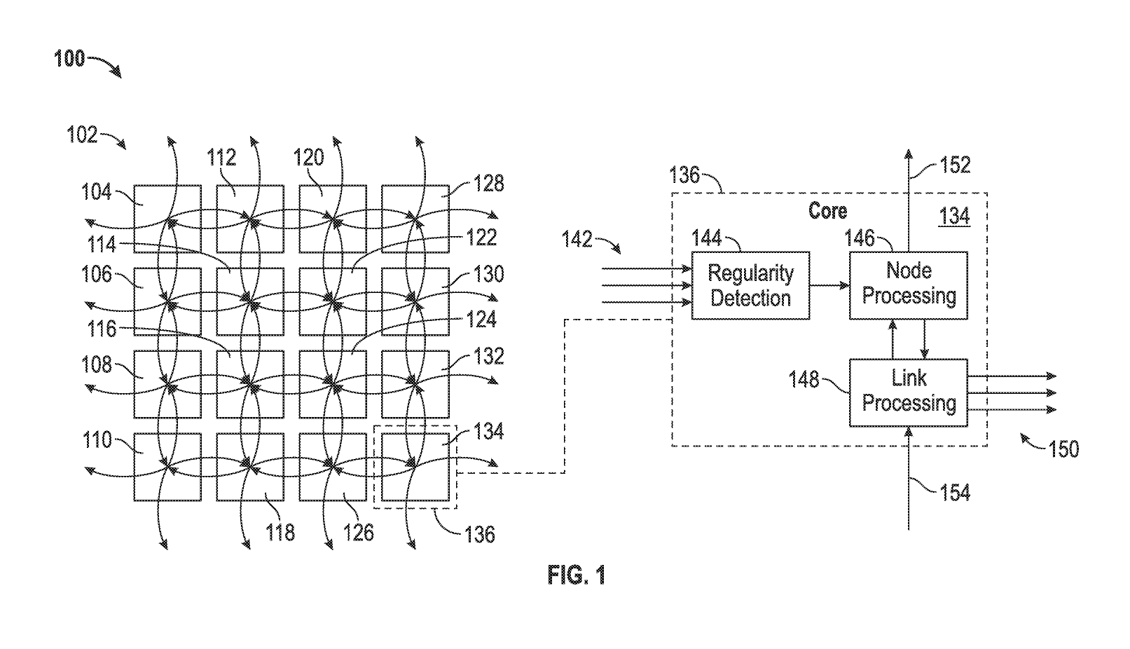

FIG. 1 illustrates a schematic diagram of cores arranged in a fabric architecture 100, which may (or may not) be locally-connected, in accordance with the disclosed embodiments. In the example shown in FIG. 1, a group or system 102 of cores can be configured, including cores 104 to 134. Core 134 is shown surrounded by a dashed line 136. A larger view of core 134 is shown by way of example to demonstrate generally how each core functions. For example, core 134 can include a regularity detector 144 that provides output, which is provided as input to a node processing unit or module 146. Energy input can be provided via one or more inputs 142 to the regularity detector 144, Energy input return is indicated by arrow 152 with respect to the node processing unit or module 146. A link processing module 148 or component receives data from and sends back to the node processing unit 146. Arrows 150 indicate energy outputs. Energy output return with respect to the link processing module 148 is indicated by arrow 154.

As mentioned, the fundamental operation of a core is to allocate energy from incoming to nodes to specific internal nodes depending on the particular spatial pattern (regularity). It must be emphasized that cores do not communicate with cores. Rather, nodes within cores communicate to cores, while cores act as a gateway between external cores and internal cores, overseeing the proper transfer of energy and, in the case of collisions, provide a mechanism for the removal of energy from the nodal network. As such, many possible inputs are possible, even for locally-connected core meshes such as those shown in the example configuration depicted in FIG. 1.

It can be appreciated that cores can contain many thousands of nodes, although at each time step they are responsible for resolving their active input lines into just one regularity or node. A core should ideally contain at least as many nodes as it expects stable regularities on its input lines. Since many inputs are possible, and since the operation of the fabric (and the real-world) is stochastic, it is important that the core have a mechanism to efficiently recognize distinct input regularities even in the presence of noise. We have previously disclosed such a regularity extraction mechanism.

Once a regularity has been recognized and assigned to a node, energy transfer must take place. In what follows, we will assume an equivalence between the particle and energy so that having twice as much particle is to have twice as much energy, and visa versa. Four mechanisms of energy transfer are possible. First, two or more particles may collide at a node. When this occurs, energy may be liberated from the nodal network. Second, a particle may bifurcate into two or more pathways, each leading to different nodes within different cores. The energy may not distribute equally between the two branches, although it must not be created or destroyed. Third, the energy may translate to one other node in another core. Fourth, the energy may decay into the fabric substrate or ground. Energy is only created through sensory events in the external world (the input data stream) and destroyed through particle collisions or decay. Each node may maintain an energy capacity such that once it has attained its capacity no additional energy may be added. That is, if the receiving node's energy capacity has been reached it will reject any new energy.

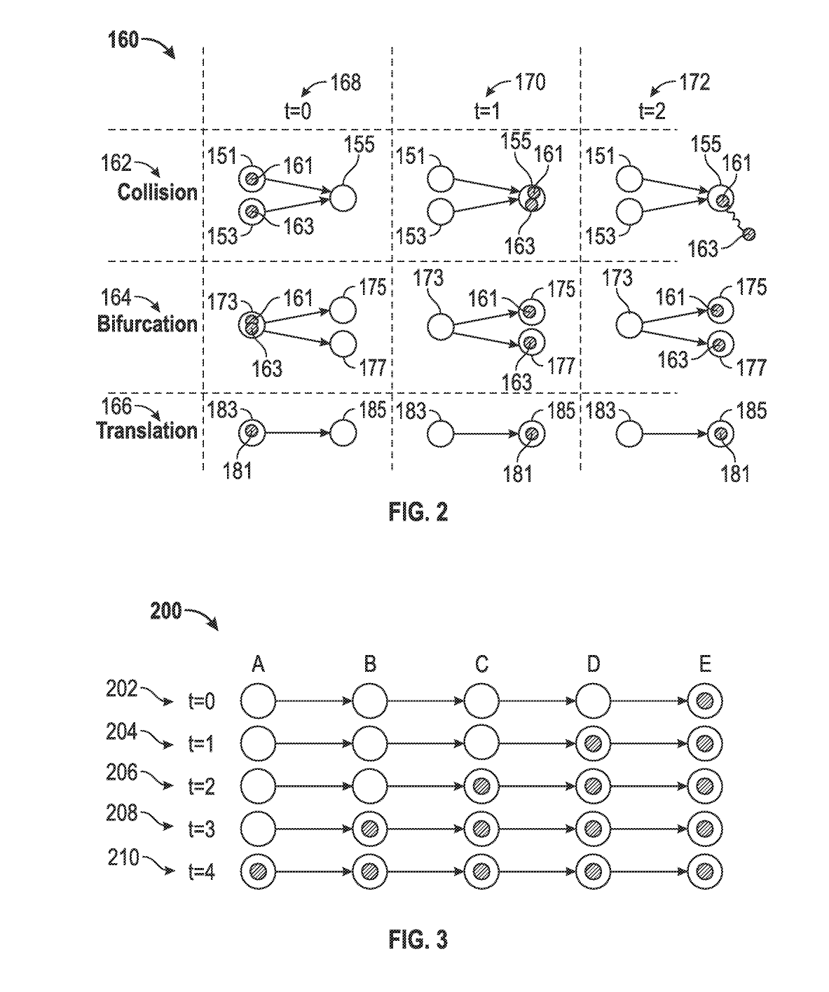

FIG. 2 illustrates a schematic diagram of three possible interactions in a system 160, in accordance with the disclosed embodiments. The three possible interactions include, for example, collisions 162, bifurcations 164, and translations 166. Note that the only way to remove energy from the system aside from decay is during particle collisions. It can be appreciated that the core fabric must contain a finite number of nodes and therefore, if a perfect energy-dissipating structure cannot be evolved, it will fill up. Once the nodes have attained capacity, they must be drained in anticipation of a new period of learning. It is thus critical that the fabric undergo a period of stasis so as to allow the energy to be depleted. This may occur through decay mechanisms.

FIG. 3 illustrates a schematic diagram of a system 200 demonstrating how once node capacity has been attained, the nodes will fill up and prevent flow, in accordance with the disclosed embodiments. Times 202, 204, 206, 208, and 210 (respectively, t=0, t=1, t=2, t=3, t=4) are shown in FIG. 3. In general, if a node has reached its capacity and cannot unload its energy at the rate it is acquiring it, the energy will backup behind it, filling up each node along the energy-dissipating pathway that ended with the node. If such an event occurs, the energy flow over the links weakens or goes to zero and the link structure dissipates, prompting reconfigurations.

Once the regularity detector has assigned a node to the current regularity, it must provide for two functions. It must receive energy from the sending nodes and it must send energy to receiving nodes. A few methods exist to model the flow of energy. Indeed, since the mechanism of energy flow is central to the field of electronics, the process may be reduced to a physical architecture rather than a computational one, which would of course result in exceptionally high efficiencies.

The schematic diagram of system 200 demonstrates that each nodes local objective function is to unload as much energy as possible. In an architecture where energy packets must be virtualized within data packets, it is important that the node send the energy along those pathways, which it is least likely to be returned. This path is determined from this history of the nodes operation. That is, pathways that have reliably sunk energy in the past should continue to sink energy in the future. A record of prior energy flow over links can be recorded on, for example, a memristor,

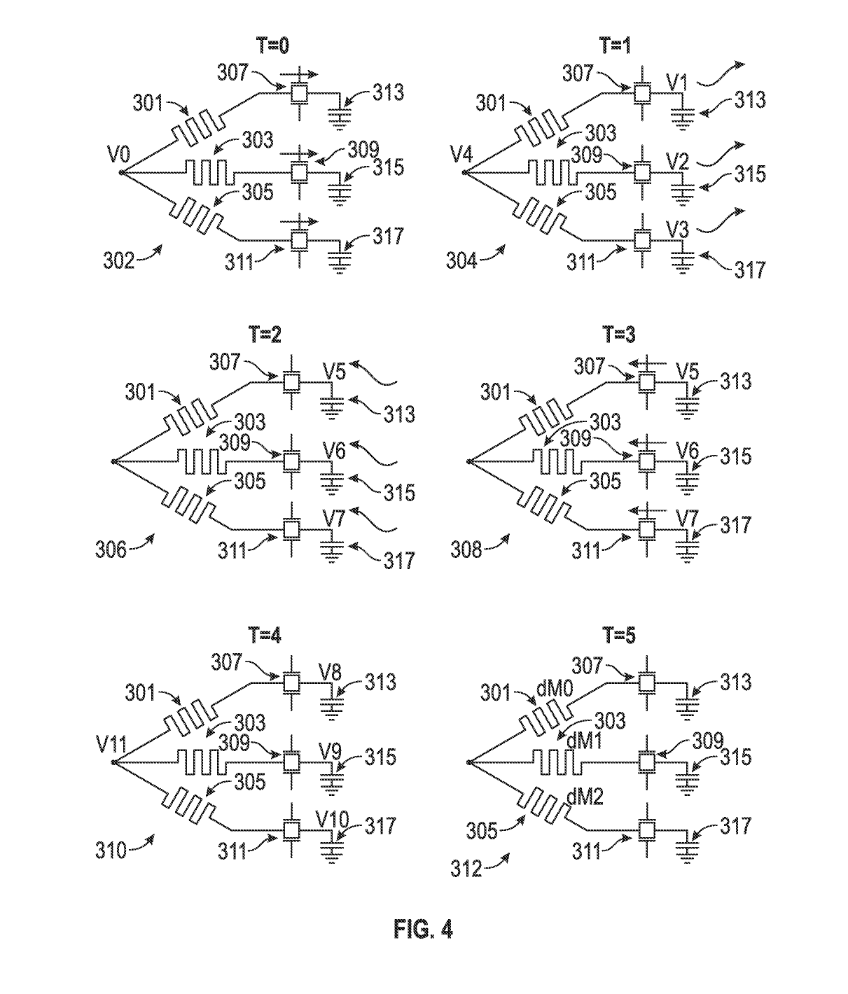

FIG. 4 illustrates a schematic diagram at various times demonstrating how one or more or a group of memristors may act as adaptive energy flow conduits which will increase conductance as energy flow through them, in accordance with the disclosed embodiments. A first memristor is associated with electronic components 301, 307, and 313. A second memristor is associated with electronic components 303, 309, and 315. A third memristor is associated with electronic components 305, 311, and 317. Such memristors are generally shown in FIG. 4 at times 302, 304, 306, 308, 310, and 312 (respectively, T=0, T=1, T=2, T=3, T=4, and T=5).

As shown in FIG. 4, starting from T=0, a voltage V0 can be applied, which causes energy to flow onto the capacitors (e.g., capacitors 313, 315, 317). At T=1, the voltage can be communicated to other nodes, where each voltage represents an energy that will be communicated to other cores. The voltage on each capacitor is in proportion to the memristor conductance (e.g., conductance represented by component/conductance 301, 303, 305, etc.) such that higher conductance will result in faster charges and higher voltages in a set unit of time. It is important that the increment of time allowing for charging is of sufficiently short duration such that the equilibrium value is not attained.

The receiving cores will process the incoming particles and accept all or a portion (or none) of the energy. Receipt of energy returned will be provided on the capacitors at T=2. Let us presume that in the meantime the node previously holding voltage V4 was set to ground. Current will flow through the memristors resulting in voltages V8, V9, V10, and V11. The change in the memristor conductance is a measure of the total current that has flown through it. Some memristors will increase in conductance if current is flowing in one direction and decrease in conductance if it is flowing the opposite direction. The result is a change to the memristor conductance, dM. As more energy is dissipated in a particular direction, more energy is allocated in that direction. In this example, we show a physical circuit that naturally adapts itself to solve the energy allocation problem.

It can be appreciated that multiple mechanisms, which achieve the same end as outlined above, are possible. For example, the memristors may be arranged in series and the inverse of the voltage drop across each memristor would give the allocation. Feedback would then be delivered by selectively applying a high voltage bias across just one of the memristors in the series. Most generally it can be appreciated that it's the ability of a memristor to act as a record of prior energy dissipating that is critical in their use as a mechanism for solving the energy routing/allocation problem as we have described it.

It is of course possible to simulate such a mechanism at multiple levels of abstraction. For example, a computational structure may be created that performs the necessary additions, subtractions, and multiplications which simulate adaptive weights or probabilities as energy flows over them. This could be represented in a CPU or ASIC circuit structure, which is a well developed modern methodology.

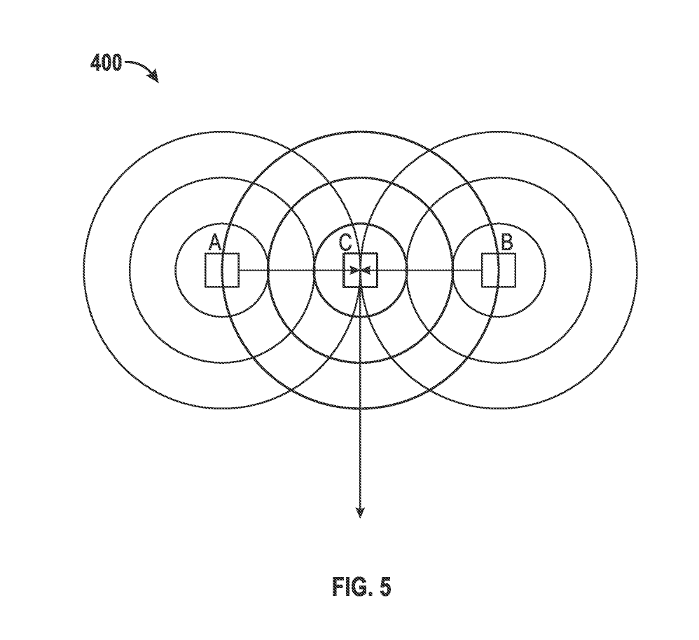

FIG. 5 illustrates a schematic diagram demonstrating how particle collisions create regions of energy sink, which lead to flow-stabilization over links in a link structure 400, in accordance with the disclosed embodiments. In general, the link structure 400 includes or encompasses nodes A, C, and B shown in FIG. 5. The configuration shown in FIG. 5 allows us to move to a higher level of abstraction to visualize the formation of logic pathways from temporal inputs. Recall that energy flows from a source to a sink and that collisions dissipate energy, which leads to a sink. Let us imagine a sheet of cores connected with a local topology. Further suppose that nodes within cores A and B were activated through external sensors and each given some unit of energy during the activation. The energy of each activation spreads out radially. When the two wave propagations meet at core C, they register as a collision and energy is dissipated. The energy that was not dissipated can further propagate into the fabric. Note that this event has left energy spread out over the nodes along the path of the wave propagations. As we are not dealing with the equilibrium conditions, more energy will be built up on nodes closer to the signal sources.

As nodes A and B are further activated, energy further builds up. As energy builds up, less energy is distributed over the node links in each unit of time. Except, of course, along the pathway that leads reliably to the collision at C. In this particular direction, energy-flow has reduced the energy level and thus the resistance to energy flow. The memristors along this pathway will grow strong and more energy will be allocated in that direction. A circuit will form that represents the conjunction of signals A and B and further propagate into the network, where additional collisions may occur. The amount of energy we remove from the collisions is of course arbitrary if it is a computational process and set by the physical characteristics of the circuit if it is a physical device.

It is not terribly difficult to now understand how the core fabric is used to evolve circuit structure that comes to represent a reflection of the causal processes that are occurring in the sensory data stream. Only by evolving a link structure which models the processes occurring in the sensory data stream will all energy be dissipated. Over time, circuits are formed as energy dissipative “rivers” around “mountains” represented tried-and-failed pathways. If a pathway no longer succeeds in dissipating energy, i.e. it no longer leads to a collision, the energy in the local valley will build up until it is on-par with the “mountains”, at which point the signals will be broadcast out onto the “plateau” in search of a new reliable sink.

By measuring the local and global energy dissipation, which is simply a measure of the particle collision rate, we can perform a measure of the “normality” of the sensory data stream, If the fabric is able to evolve a stable flow network, the relative amounts of energy dissipated in each region of the fabric remain constant. During a change from normal statistics in the data stream, the evolved structure of the fabric will of course change as it adapts. This change can be related to a metric and a threshold such that if the threshold is crossed an alert will be sent to interested parties.

Based on the foregoing, it can be appreciated that a number of embodiments, preferred and alternative, are disclosed herein, For example, in one embodiment a spatial-temporal regularity extraction fabric apparatus can be disclosed which includes a plurality of interacting cores, wherein the plurality of interacting cores receives activations containing energy or particles, wherein each core among the plurality of interacting cores is configured to map input activation patterns arising from external nodal activations to internal nodes within the plurality of interacting cores, and wherein the energy or the particles are transferred between the internal nodes within the plurality of interacting cores.

In another embodiment, the aforementioned energy can be liberated when the activations collide within at least one core among the plurality of interacting cores. In other embodiments, the spatial-temporal regularity extraction fabric apparatus can be configured for anomaly detection.

In another embodiment, a change in a power dissipation rate can be compared to a threshold value and employed to trigger an alert regarding the anomaly detection.

In yet other embodiments, the aforementioned energy can be liberated when the activations collide within at least one core among the plurality of interacting cores. In other embodiments, the spatial-temporal regularity extraction fabric apparatus can be configured for anomaly detection.

In other embodiments, a change in a power dissipation rate can be compared to a threshold value and employed to trigger an alert regarding the anomaly detection.

In another embodiment, a spatial-temporal regularity extraction fabric apparatus can include a plurality of interacting cores, wherein the plurality of interacting cores receives activations containing energy or particles, wherein each core among the plurality of interacting cores is configured to map input activation patterns arising from external nodal activations to internal nodes within the plurality of interacting cores, and wherein the energy or the particles are transferred between the internal nodes within the plurality of interacting cores, wherein the energy is liberated when the activations collide within at least one core among the plurality of interacting cores and wherein the spatial-temporal regularity extraction fabric apparatus is configured for anomaly detection.

In another embodiment, an apparatus for adaptive energy allocation can be included, which includes a plurality of memristors that function as adaptive energy flow conduits.

In another embodiment, an anomaly-detecting fabric system can include a plurality of interacting cores in a nodal network having a link structure, wherein the plurality of interacting cores receives and processes a spatial-temporal data stream, wherein each core among the plurality of interacting cores is configured to solve for anomaly detection by creating energy during sensory input to the at least one input and a dissipation of energy during collisions of nodal activations with respect to the nodal network; and at least one input to each core among the plurality of interacting cores, the at least one input providing the spatial-temporal data stream, wherein the each core among the plurality of interacting cores receives the at least one input and functions as a regularity detector to recognize statistical regularities with respect to the at least one input and permit the plurality of interacting cores to detect anomalies with respect to the spatial-temporal data stream.

In another embodiment, the aforementioned input lines can receive inputs that share a high degree of mutual information, In other embodiments, each nodal activation can comprise a particle. In yet other embodiments, a prediction can be defined as at least one collision of two or more particles at at least one core among the plurality of interacting cores, which form a regularity detectable by the regularity detector. In other embodiments, when the at least one collision occurs, energy can be liberated from the nodal network causing increased energy flow in a direction of the at least one collision and a reinforcement of the link structure.

In yet another embodiment, after a period a stable flow structure occurs, which acts to annihilate energy introduced to the sensory inputs via particle collisions so that the stable flow structure mirrors a structure of the spatial-temporal data stream. In still other embodiments, the aforementioned input lines can receive inputs that share a high degree of mutual information and wherein each nodal activation comprises a particle.

In another embodiment, a method for configuring a spatial-temporal regularity extraction fabric apparatus can be implemented. Such a method can include, for example, the steps or logical operations of providing a plurality of interacting cores, wherein the plurality of interacting cores receives activations containing energy or particles; and configuring each core among the plurality of interacting cores to map input activation patterns arising from external nodal activations to internal nodes within the plurality of interacting cores such that the energy or the particles are transferred between the internal nodes within the plurality of interacting cores.

In another embodiment, the aforementioned can be liberated when the activations collide within at least one core among the plurality of interacting cores. In other embodiments, a step or logical operation can be implemented for configuring the spatial-temporal regularity extraction fabric apparatus for anomaly detection.

In other embodiments, a change in the power dissipation rate can be compared to a threshold value and employed to trigger an alert regarding the anomaly detection. In still other embodiments, the aforementioned energy can be liberated when the activations collide within at least one core among the plurality of interacting cores.

In general, a fabric of cores can be configured to spontaneously organize internal structure that mirrors the spatial-temporal causal structure of the data stream that is injected into the fabric. The mechanism is that of a self-organizing energy dissipating structure such that the energetic source is the injected signals and the energetic sink is the collisions of signals in cores. An adaptive routing architecture is further possible such that energy is preferentially allocated in the direction of maximal energy sink. By measuring the energy dissipation rate, anomalies may be detected by comparing to a set threshold.

It will be appreciated that variations of the above-disclosed and other features and functions, or alternatives thereof, may be desirably combined into many other different systems or applications. Also, that various presently unforeseen or unanticipated alternatives, modifications, variations or improvements therein may be subsequently made by those skilled in the art which are also intended to be encompassed by the following claims.

what is claimed is:

1. A spatial-temporal regularity extraction fabric apparatus, comprising:
a plurality of interacting cores, wherein said plurality of interacting cores receives activations containing energy or particles, wherein each core among said plurality of interacting cores is configured to map input activation patterns arising from external nodal activations to internal nodes within said plurality of interacting cores, and wherein said energy or said particles are transferred between said internal nodes within said plurality of interacting cores.

2. The apparatus of claim 1 wherein said energy is liberated when said activations collide within at least one core among said plurality of interacting cores.

3. The apparatus of claim 1 wherein said spatial-temporal regularity extraction fabric apparatus is configured for anomaly detection.

4. The apparatus of claim 3 wherein a change in a power dissipation rate is compared to a threshold value and employed to trigger an alert regarding said anomaly detection.

5. The apparatus of claim 1 wherein said energy is liberated when said activations collide within at least one core among said plurality of interacting cores,

6. The apparatus of claim 5 wherein said spatial-temporal regularity extraction fabric apparatus is configured for anomaly detection.

7. The apparatus of claim 6 wherein a change in a power dissipation rate is compared to a threshold value and employed to trigger an alert regarding said anomaly detection.

8. The apparatus of claim 1 wherein:
said energy is liberated when said activations collide within at east one core among said plurality of interacting cores;
said spatial-temporal regularity extraction fabric apparatus is configured for anomaly detection; and
a change in a power dissipation rate is compared to a threshold value and employed to trigger an alert regarding said anomaly detection.

9. A spatial-temporal regularity extraction fabric apparatus, comprising:
a plurality of interacting cores, wherein said plurality of interacting cores receives activations containing energy or particles, wherein each core among said plurality of interacting cores is configured to map input activation patterns arising from external nodal activations to internal nodes within said plurality of interacting cores, and wherein said energy or said particles are transferred between said internal nodes within said plurality of interacting cores, wherein said energy is liberated when said activations collide within at least one core among said plurality of interacting cores and wherein said spatial-temporal regularity extraction fabric apparatus is configured for anomaly detection.

10. The apparatus of claim 9 wherein a change in a power dissipation rate is compared to a threshold value and employed to trigger an alert regarding said anomaly detection.

11. The apparatus of claim 9 wherein said plurality of interacting cores comprises receiving cores that process incoming particles with respect to said particles and accepts all or a portion of said energy.

12. The apparatus of claim 9 wherein a change in a power dissipation rate is compared to a threshold value and employed to trigger an alert regarding said anomaly detection and wherein said plurality of interacting cores comprises receiving cores that process incoming particles with respect to said particles and accepts all or a portion of said energy.

13. An apparatus for adaptive energy allocation, said apparatus comprising:
a plurality of memristors that function as adaptive energy flow conduits.

14. An anomaly-detecting fabric system, comprising:
a plurality of interacting cores in a nodal network having a link structure, wherein said plurality of interacting cores receives and processes a spatial-temporal data stream, wherein each core among said plurality of interacting cores is configured to solve for anomaly detection by creating energy during sensory input to said at least one input and a dissipation of energy during collisions of nodal activations with respect to said nodal network; and
at least one input to each core among said plurality of interacting cores, said at least one input providing said spatial-temporal data stream, wherein said each core among said plurality of interacting cores receives said at least one input and functions as a regularity detector to recognize statistical regularities with respect to said at least one input and permit said plurality of interacting cores to detect anomalies with respect to said spatial-temporal data stream.

15. The system of claim 14 wherein said input lines receive inputs that share a high degree of mutual information,

16. The system of claim 14 wherein each nodal activation comprises a particle.

17. The system of claim 14 further comprising a prediction defined as at least one collision of two or more particles at at least one core among said plurality of interacting cores, which form a regularity detectable by said regularity detector

18. The system of claim 17 such that when said at least one collision occurs, energy is liberated from said nodal network causing increased energy flow in a direction of said at least one collision and a reinforcement of said link structure.

19. The system of claim 14 wherein after a period, a stable flow structure occurs, which acts to annihilate energy introduced to said sensory inputs via particle collisions so that said stable flow structure mirrors a structure of said spatial-temporal data stream.

20. The system of claim 14 wherein said input lines receive inputs that share a high degree of mutual information and wherein each nodal activation comprises a particle.
